(19) United States
(12) Patent Application Publication
(10) Pub. No.: US 2011/0041916 A1
(43) Pub. Date: Feb. 24, 2011

(54) LENS WITH A DETERMINED PITCH

(75) Inventors: YU-SHU CHEN, Chu-Nan (TW); AN-CHI WEI, Chu-Nan (TW); CHIH-CHUNG TSAO, Chu-Nan (TW); SHAN-JU LIN, Chu-Nan (TW)

Correspondence Address: Altis Law Group, Inc.;ATTN: Steven Reiss, 288 SOUTH MAYO AVENUE, CITY OF INDUSTRY, CA, 91789, US

(73) Assignee: FOXSEMICON INTEGRATED TECHNOLOGY, INC., Chu-Nan (TW)

(21) Appl. No.: 12/835,743

(22) Filed: Jul. 14, 2010

(30) Foreign Application Priority Data
Aug. 19, 2009 (CN) 200910305795.6

(51) Int. Cl. H01L 31/0232; G02B 3/08

(52) U.S. Cl. 136/259; 359/742

(57) ABSTRACT

A non-imaging lens includes a transparent member, a conical protrusion, and a plurality of annular protrusions. The transparent member includes a first surface and a second surface. The first surface and the second surface are planar. The conical protrusion is defined on the first surface of the transparent member. The annular protrusions are concentrically defined on the first surface around the conical protrusion. Each of cross-sections of the annular protrusions approximately forms a right triangle. Each of the triangles includes a first angle, a second angle, a bottom surface, a first surface and a second surface. The first angle exceeds the second angle. The first angle is less than or equal to 90°. The second angles increase in turn outwards from the conical protrusion. The width of the bottom surface is equal to the radius of the conical protrusion.

### CROSS-REFERENCE TO RELATED APPLICATIONS

This application is related to patent application Ser. No. ______, entitled “LENS WITH INCREASING PITCHES” and filed on ______, 2010 (Attorney Docket No. US26738) and patent application Ser. No. ______, entitled “LENS WITH MULTIPLE PROTRUSIONS” and filed on ______, 2010 (Attorney Docket No. US26739). Such applications have the same inventors and assignee as the present application.

### BACKGROUND

1. Technical Field

The disclosure relates generally to lenses, and more particularly to a lens for condensing solar light.

2. Description of the Related Art

Generally, solar light is considered to be aligned. A standard Fresnel lens is configured for concentrating the solar light for a solar cell. However, the intensity of light through the Fresnel lens is not uniform. When the solar light passes through the Fresnel lens, the intensity of the center is normally higher than that at the periphery. Thus, what is called for is a lens that can overcome the limitations described.

### BRIEF DESCRIPTION OF THE DRAWINGS

FIG. 1 is a top view of a non-imaging lens in accordance with a first embodiment of the disclosure.

FIG. 2 is a cross-section along line II-II of the non-imaging lens in FIG. 1.

FIG. 3 is a cross-section of the non-imaging lens in FIG. 1.

FIG. 4 is a cross-section of the non-imaging lens in FIG. 1 in a vertical orientation, showing an optical path of the non-imaging lens in FIG. 1

FIG. 5 is a cross-section of a non-imaging lens in accordance with a second embodiment of the disclosure.

FIG. 6 is a cross-section of a non-imaging lens in accordance with a third embodiment of the disclosure.

FIG. 7 is a view similar to FIG. 4, showing a solar cell module utilizing the non-imaging lens in FIG. 1.

### DETAILED DESCRIPTION

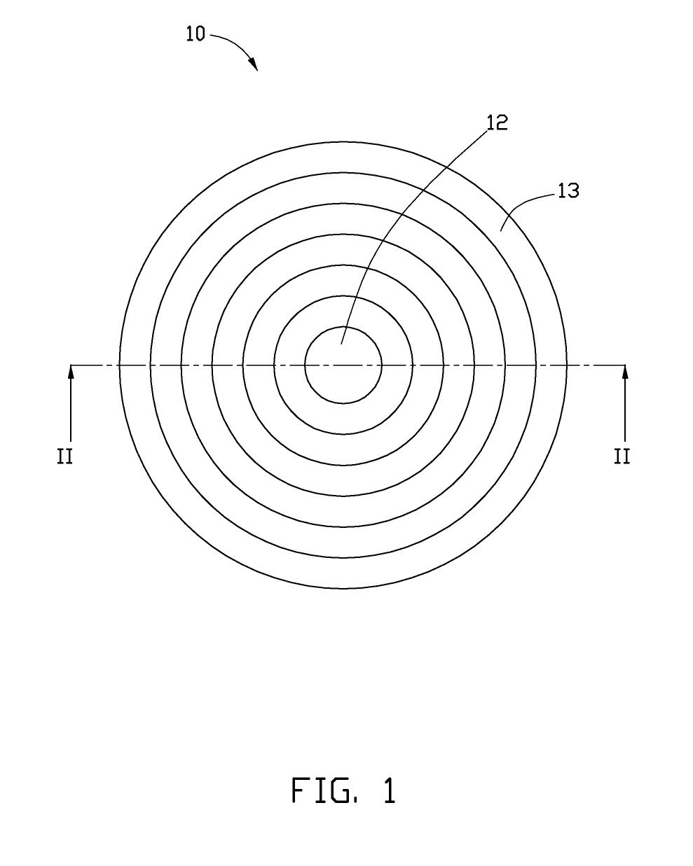

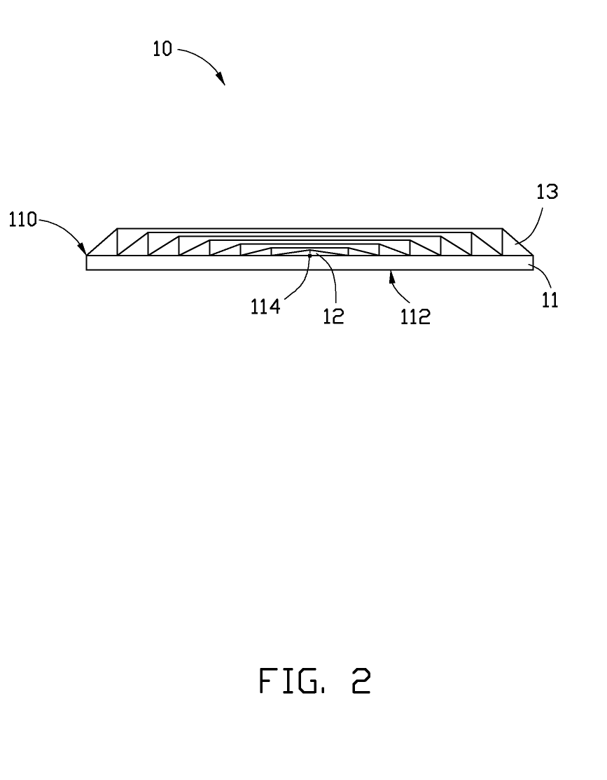

Referring to FIG. 1 and FIG. 2, a non-imaging lens 10 in accordance with a first embodiment of the disclosure includes a transparent member 11, a conical protrusion 12 and a plurality of annular protrusions 13.

The transparent member 11 is circular. The transparent member 11 includes a first surface 110 and a second surface 112. The second surface 112 is configured for receiving the solar light. The first surface 110 and the second surface 112 are planar. The transparent member 11 is made of resin or glass.

The conical protrusion 12 is defined at a center 114 of the first surface 110. A center (not labeled) of the conical protrusion 12 is coincident with the center 114 of the first surface 110. The annular protrusions 13 are concentrically defined on the first surface 110 around the conical protrusion 12. Each of cross-sections along the line II-II of the protrusions 13 approximately forms a right-angled triangle at a side of the center 114 of the first surface 110 of the transparent member 11. Each of the triangles includes a first bottom surface 130, a first surface 132 which is perpendicular to the bottom surface 130, a second surface 134 which is slantwise to the bottom surface 130, a first angle θ, a second angle α and a third angle γ. The bottom surfaces 130 of the triangles are on the first surface 110. The first surfaces 132 are located towards the conical protrusion 12. The widths of the bottom surfaces 130 are uniform. The second angles α increase in turn outwards from the conical protrusion 12. The first angle θ is 90°. The third angles γ decrease in turn outwards from the conical protrusion 12.

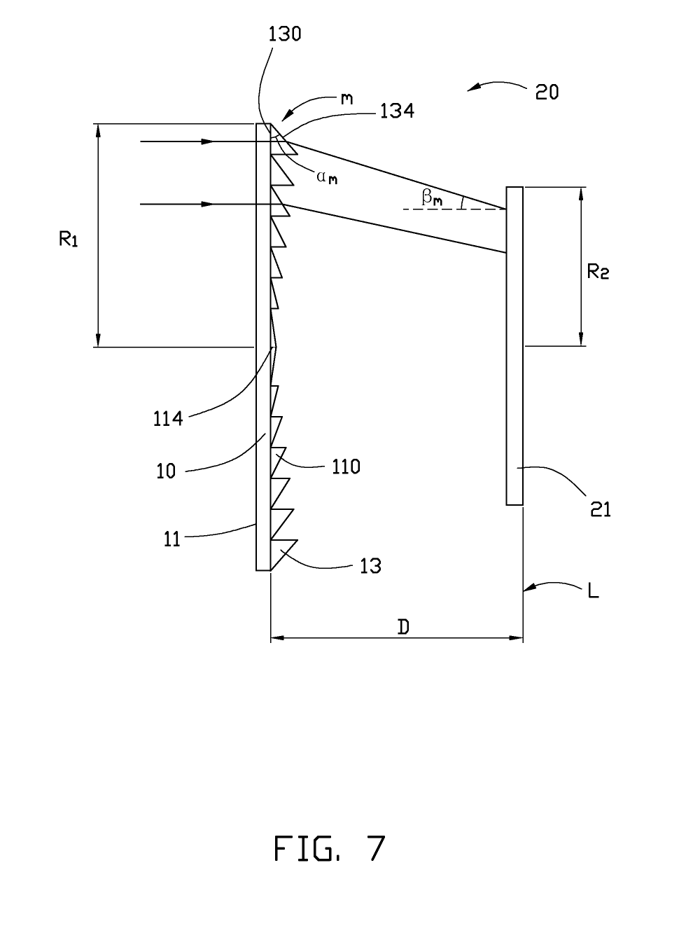

The conical protrusion 12 is considered as forming two triangles at two sides of the center 114, wherein each triangle formed by the conical protrusion 12 is deemed as the first triangle in counting the triangles formed by the conical protrusion 12 and the annular protrusions 13 in the formulae for constructing a solar cell module of the disclosure as detailed below in connection with FIG. 7. The radius of the conical protrusion 12 is equal to a width of each of the bottom surfaces 130.

The transparent member 11 can be triangular or elliptical, there being no limitation to the shape as disclosed.

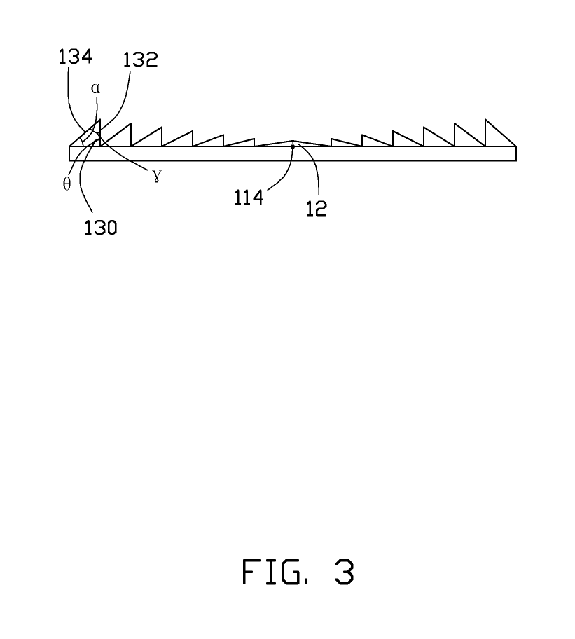

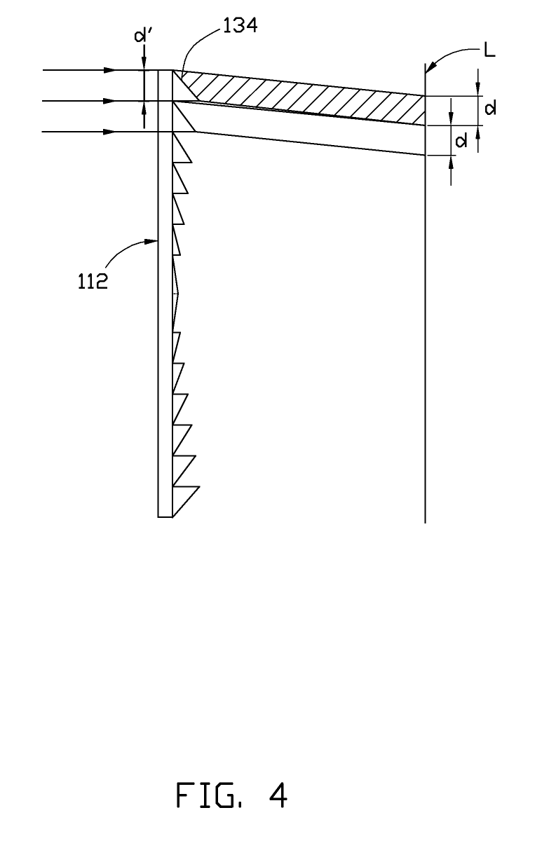

Referring to FIG. 3 and FIG. 4, the second surface 134 of each of the triangle is configured for refracting the solar light. The widths d of light spots corresponding to the protrusions 13 on the L plane are uniform.

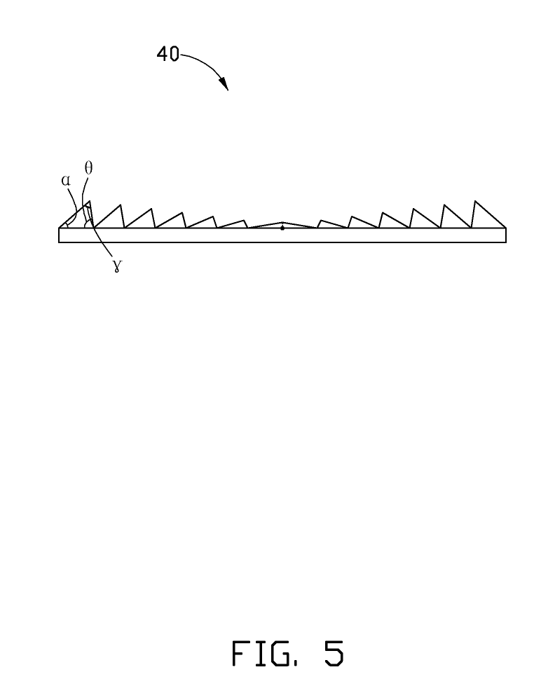

Referring to FIG. 5, a non-imaging lens 40 in accordance with a second embodiment of the disclosure is similar to the first embodiment, differing only in that the first angle θ is between 45° and 90° and the first angle θ exceeds the second angle α. For example, the first angle θ could be between 87° and 90°.

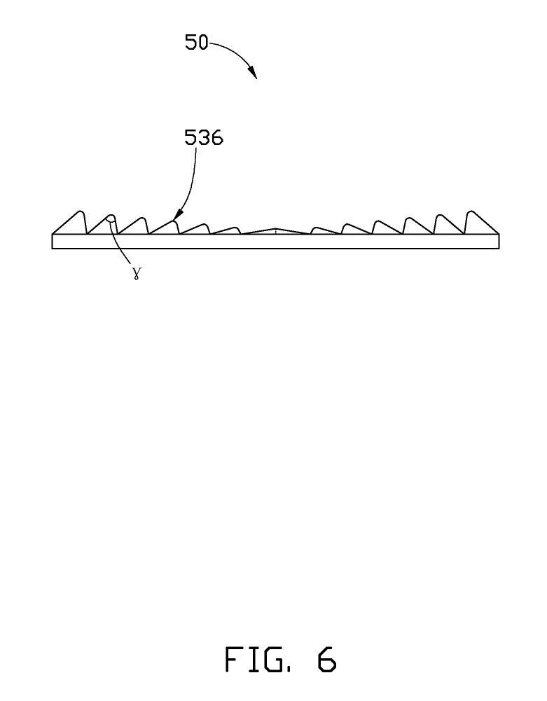

Referring to FIG. 6, a non-imaging lens 50 in accordance with a third embodiment of the disclosure is similar to the non-imaging lens 40 of the second embodiment, differing only in that a corner 536 of each of the triangles formed by the annular protrusions in cross section corresponding to the third angle γ is a smooth corner.

Referring to FIG. 7, a solar cell module 20 includes a solar cell plate 21 and a non-imaging lens 10 as shown in FIG. 1. The solar cell plate 21 is defined on L plane of FIG. 4 towards the annular protrusions 13 of the lens 10 for efficiently receiving the solar light. The number of the annular protrusions 13, a radius of the transparent member 11 and a radius of the solar cell plate 21 can be determined according to specific requests. When the parameters of the solar cell module 20 satisfy formula (1) and formula (2), uniform solar light is received by the solar cell plate 21.

$$\begin{matrix}{β}_{m} = {tan}^{- 1} \{ \frac{( {R}_{1} / {m}_{max} - {R}_{2} / {m}_{max} ) ( 2 m - 1 )}{2 D} \} & ( 1 ) \\ {α}_{m} = {tan}^{- 1} \{ \frac{sin {β}_{m}}{n - cos {β}_{m}} \} & ( 2 )\end{matrix}$$

R₁ is the radius of the transparent member 11. R₂ is the radius of solar cell plate 21. D is a distance between the solar cell plate 21 and the first surface 110 of the transparent member 11. mₘₐₓ is total number of the triangles at a side of the transparent member 11 relative to the center 114, which in the embodiment of FIG. 7 is seven (7). The conical protrusion 12 forms two triangles beside the center 114.

Either of the triangles defined by the conical protrusion 12 is considered as the first triangle. Either of the triangles defined by the outermost annular protrusion 13 is considered as the last triangle. αₘ is the second angle of the m^{th} triangle. βₘ is an incident angle relative to the solar light plate 21 of light through the m^{th} triangle. n is a refractive coefficient of the non-imaging lens 10.

Uniform intensity can be easily obtained utilizing the non-imaging lens 10 satisfying the formulae (1) and (2).

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A non-imaging lens comprising:
a transparent member comprising a first surface and a second surface, the first surface and the second surface configured to be planar;
a conical protrusion; and
a plurality of annular protrusions, the conical protrusion defined on the first surface of the transparent member, the annular protrusions concentrically defined on the first surface of the transparent member and configured around the conical protrusion, each of cross-sections of the annular protrusions at a side of a center of the transparent member forming a triangle, the triangle comprising a first angle, a second angle, a bottom surface, a first surface and a second surface, the first angle defined by the bottom surface and the first surface, the second angle defined by the bottom surface and the second surface, the first angle exceeding the second angle, the first angle configured to be less than or equal to 90°, the second angles of the triangles configured to increase in turn outwards from the conical protrusion, and each of the widths of the bottom surfaces configured to be equal to the radius of the conical protrusion.

2. The lens as claimed in claim 1, wherein the first angles of the triangles are uniform.

3. The lens as claimed in claim 1, wherein the first angle is between 45° and 90°.

4. The lens as claimed in claim 3, wherein the first angle is between 87° and 90°.

5. The lens as claimed in claim 4, wherein the first angle is 90°.

6. The lens as claimed in claim 1, wherein each of the triangles further comprises a third angle and a smooth corner corresponding to the third angle.

7. The lens as claimed in claim 1, wherein the transparent member is circular.

8. A solar cell module comprising:
a non-imaging lens comprising:
a transparent member comprising a first surface and a second surface, the first surface and the second surface configured to be planar;
a conical protrusion; and
a plurality of annular protrusions, the conical protrusion defined on the first surface of the transparent member, the annular protrusions concentrically defined on the first surface of the transparent member and configured around the conical protrusion, each of cross-sections of the annular protrusions at a side of a center of the transparent member forming a triangle, the triangle comprising a first angle, a second angle, a bottom surface, a first surface and a second surface, the first angle defined by the bottom surface and the first surface, the second angle defined by the bottom surface and the second surface, the first angle exceeding the second angle, the first angle configured to be less than or equal to 90°, the second angles of the triangles configured to increase in turn outwards from the conical protrusion, and each of the widths of the bottom surfaces configured to be equal to the radius of the conical protrusion; and
a circular solar cell plate, the solar cell plate defined parallel to the lens and configured towards a plurality of protrusions of the lens, the solar cell module satisfying the formulae:
$$\begin{matrix}{β}_{m} = {tan}^{- 1} \{ \frac{( {R}_{1} / {m}_{max} - {R}_{2} / {m}_{max} ) ( 2 m - 1 )}{2 D} \} , \\ {α}_{m} = {tan}^{- 1} \{ \frac{sin {β}_{m}}{n - cos {β}_{m}} \} ,\end{matrix}$$
wherein R₁ is a radius of the transparent member, R₂ is a radius of the solar cell plate, D is a distance between the solar cell plate and the first surface of transparent member of the lens, mₘₐₓ is total number of the triangles formed by the annular protrusions at the side of the center of the transparent member and an additional triangle formed by a cross section of the conical protrusion, the additional triangle is considered as the first triangle while the triangle formed by an outermost annular protrusion is deemed as the last triangle, αₘ is the second angle of the m^{th} triangle, βₘ is an incident angle relative to the solar cell plate of light through the m^{th} triangle, and n is a refractive coefficient of the non-imaging lens.

9. The solar cell module as claim 8, wherein the first angles of the triangles are uniform.

10. The solar cell module as claim 9, wherein first angles of the triangles each are 90°.

11. The solar cell module as claim 8, wherein each of the triangles further comprises a third angle and a smooth corner corresponding to the third angle.
